(19) United States
(12) Patent Application Publication
(10) Pub. No.: US 2025/0204137 A1
(43) Pub. Date: Jun. 19, 2025

(54) OPERATING ELEMENT AND METHOD

(71) Applicant: ams-OSRAM International GmbH, Regensburg (DE)

(72) Inventors: Patrick HOERNER, Bamberg (DE); Marc PHILIPPENS, Regensburg (DE); Erwin LANG, Regensburg (DE); Andreas RAUSCH, Tegernheim (DE); Michael JOBST, Wiesenfelden (DE); Meik WECKBECKER, Thalmassing (DE)

(21) Appl. No.: 18/834,941

(22) PCT Filed: Feb. 1, 2023
(86) PCT No.: PCT/EP2023/052440

§ 371 Date: Jul. 31, 2024

(30) Foreign Application Priority Data
Feb. 1, 2022 (DE) 10 2022 102 368.0

(51) Int. Cl. H10H 29/80; G06F 3/041; H10H 29/856

(52) U.S. Cl. CPC H10H 29/882; G06F 3/0412; H10H 29/856

(57) ABSTRACT

An operating element includes a carrier element, a luminous foil in or on which at least one optoelectronic component for generating light along a first main radiation direction and contact lines connected thereto are arranged, a diffuser layer arranged after the at least one optoelectronic component with respect to the first main radiation direction, a structured symbol element which is not arranged in front of the diffuser layer with respect to the first main radiation direction and configured to image at least one symbol along the first main radiation direction in a top view onto the diffuser layer and during operation of the at least one optoelectronic component, a touch-sensitive sensor configured to detect an exerted touch or pressure and to generate an electrical signal, and at least one reflective layer configured to reflect light scattered in the opposite direction to the main radiation direction in the main radiation direction.

The present application claims the priority of the German application DE 10 2022 102 368.0 of Feb. 1, 2022, the disclosure of which is hereby incorporated by reference in its entirety.

The present invention relates to an operating element and a control panel. The invention also relates to a method for manufacturing such an operating element.

### BACKGROUND

Due to the increasing miniaturization of LED technology, there are many possibilities for implementing display and operating elements. Well-known forms use μ-LED-based displays for this purpose. In this case, μ-LEDs are optoelectronic components that are characterized by a very small edge length in the range of a few μm to around 100 μm. In addition to the effort involved in manufacturing such displays, they are also often very expensive due to the active control required (TFT backplane & control electronics). Furthermore, they are usually rectangular in shape and therefore limited in terms of their possible applications.

There is therefore a need to create operating elements that can be used in a variety of different ways and yet are cheaper to manufacture than conventional technologies.

### SUMMARY OF THE INVENTION

This need is met by the objects of the independent patent claims. Further developments and embodiments are the subject of the subclaims.

The inventors have recognized that although display and operating elements are used in many areas, they are usually simple and clearly arranged. By simply pressing a button, these can be switched on or off with their respective function, while at the same time a light element provides a visual indication of the respective status. Applications for such operating elements can be found in the automotive sector, for example, where vehicle functions such as interior lighting or similar can be switched on or off simply by pressing a button. Illuminated controllers, which can be used for control purposes and are in turn indicated by light signals, are also included. One example would be dimmers in the smart home sector or again in the automotive sector. Other such operating elements can be found in automation and industrial technology, in aircraft construction and also in home appliances.

As each pixel of a display is “equipped” with a μLED, the majority of the LED chips are not operated in a simple display element. However, the homogeneous illumination of the display symbol required by the application should still be guaranteed, whereby the number of LEDs should be as low as possible. Furthermore, it may be necessary, for example in the automotive sector or in aircraft construction, for the integration of the display and operating element according to the invention to remain at least partially or predominantly transparent.

In order to meet the various requirements, the inventors propose the use of optoelectronic components within a flexible layer stack, whereby various symbol structures are used to display and generate a display element. These can, for example, contain structured shadow masks or structured diffuser layers within the flexible layer stack. By further integrating a transparent capacitive or resistive haptic sensor (touch sensor), an operating element is created in which not only the optoelectronic elements used are reduced, but in which the control is also significantly simplified.

In an embodiment according to the proposed principle, an operating element comprises a carrier element and a luminous foil in or on which at least two optoelectronic components and contact lines connected to them are arranged. The at least two optoelectronic components generate light along a first main radiation direction during operation. A diffuser layer is arranged downstream of the at least two optoelectronic components with respect to the first main radiation direction. In the following, “downstream” with respect to the first main radiation direction means that one element follows another element when moving along the main radiation direction. Light that is emitted by the component along the main radiation direction therefore hits the other element first.

Furthermore, a symbol element is provided which is not arranged upstream of the diffuser layer with respect to the first main radiation direction. In other words, the symbol element is thus either arranged downstream of the diffuser layer with respect to the first main radiation direction or is formed in the diffuser layer itself. When the at least two optoelectronic components are in operation and the diffuser layer is viewed from above along the first main radiation direction or in the opposite direction, the symbol element is configured to display at least one symbol. In this context, a structured symbol element is to be understood as an element which represents one or more symbols for a user. A structured symbol element may comprise one or more letters, with each letter forming a symbol of the structured symbol element. The structured symbol element can also comprise one or more characters, pictograms or icons or a combination of these with letters.

Furthermore, the operating element according to the proposed principle comprises a touch-sensitive sensor which is configured to detect a touch or pressure exerted along or in the opposite direction to the first main radiation direction and to generate an electrical signal therefrom. Finally, a reflective layer is arranged on or in a side of the carrier foil facing away from the symbol element. The inventors have recognized here that such a reflective layer leads in many cases to a significant improvement in the emitted light intensity, which has a particularly positive effect on various symbol elements. For example, a significant improvement in the transmitted light intensity was observed. The diffuser layer prevents waveguiding of light between the back of the structured symbol element and the reflective layer.

The proposed operating element creates a flexible solution that is equally suitable for a wide range of applications. The number of optoelectronic components is reduced and limited to what is necessary for homogeneous illumination and the control is significantly simplified. In some aspects, the optoelectronic components can be arranged in a matrix form or follow the shape of the symbol element, i.e. the optoelectronic components show an arrangement in plan view that is similar to the symbol to be illuminated. The operating element is formed in a flexible structure, which allows it to be easily integrated into existing carrier surfaces if necessary.

In some aspects, it is provided to achieve the necessary homogeneous illumination of the operating element and in particular of the structured symbol element by making the distance between the diffuser layer and the at least two optoelectronic components dependent on a distance between the at least two optoelectronic components.

In some aspects, the reflective layer may be disposed between the luminous foil and the tactile sensor. In other aspects, the reflective layer is disposed behind the tactile sensor. This may be useful if the foil affects the sensitivity of the sensor. In this context, the reflective layer may also have a further functionality, for example serving as a current path for supplying the touch sensor or also the at least one optoelectronic component. In this case, it is electrically connected to the touch sensor or the at least one optoelectronic component.

In some other aspects, the reflective layer comprises a thermally conductive material, in particular Al2O3, a metal or a specular reflective material. In addition to the above reflective layer, a second reflective layer may also be provided which is disposed between the structured symbol element and the diffuser layer. This can have a somewhat smaller lateral extent than the structured symbol element, so that in this way the entire surface of the structured symbol element is not covered. It has been found that a slightly smaller area, in which no reflective layer is arranged around the opening of the symbol element in particular, has a slightly higher intensity when light is emitted by the structured symbol element.

The second reflective layer is applied to the side of the structured symbol element facing the at least one optoelectronic component. Thus, during manufacture, the symbol element can be formed as a foil with an absorbent and a reflective side or only as a reflective foil.

In some aspects, the structured symbol element is formed by a shadow mask arranged on the diffuser layer with respect to the first main radiation direction. This makes it possible to create a wide variety of operating elements in a very simple manner by adapting the shadow mask. In some aspects, the distance between the diffuser layer and the at least two optoelectronic components can also be greater than half the distance between the at least two optoelectronic components. This dependence between the distance between the optoelectronic components and the diffuser layer and the distance between two neighboring optoelectronic components (pixel pitch) can be used to adjust the homogeneity of the illumination. The specified dependency creates an overlap in the light cone and thus improves the illumination.

Depending on the embodiment, the reflective layer may also be placed near the plane of the component or components in the substrate layer. In some aspects, the at least one component and the reflective layer lie substantially in a plane within or on the carrier layer. In some aspects, the distance between the reflective layer and the symbol element is also dependent on the distance between the symbol element and the at least one optoelectronic component.

In another aspect, the structured symbol element is formed by the diffusor layer, inter alia by a structuring in the diffusor layer, in particular by a spatial distribution of diffusor particles in the diffusor layer forming the structuring. Similar to the previous example, it can also be provided here that the distance between the diffuser layer and two neighboring optoelectronic components, which are assigned to the at least one symbol, is less than half the distance between the two neighboring optoelectronic components. In other words, the pixel pitch or the distance to the diffuser layer is selected such that a sufficiently large overlap is created and the assigned symbol is thus uniformly illuminated.

On the other hand, a symbol may contain several sub-symbols that should be spaced apart. It is therefore necessary that the sub-symbols can be resolved well. In the case of a structured symbol element in the diffuser layer, the resolution results from the distance between two neighboring optoelectronic components, one of which is assigned to one sub-symbol and the other to the other sub-symbol. In some aspects, a distance between the diffuser layer and two neighboring optoelectronic components, which are assigned to different symbols or sub-symbols, is thus less than half the distance between the two neighboring optoelectronic components.

In some aspects, the necessary distance between the optoelectronic components and the diffuser layer is created by an adhesive layer which bonds the luminous foil to the diffuser layer. The thickness of this layer essentially corresponds to the required distance between the diffuser layer and the at least two optoelectronic components.

In some aspects, the diffuser layer can have an electrochromic layer. This allows the symbol to be additionally darkened or further color nuances to be set. In addition to the above-mentioned layers, additional layers can be provided that implement further functionalities for the operating element. In some aspects, for example, an adhesive layer can be arranged between the carrier element and the luminous foil. The adhesive layer may be a hotmelt adhesive whose thickness is only a few 10 μm. In this context, the adhesive layer may include reflective particles and thus also form the reflective layer.

In addition, the operating element can comprise a cover foil layer that is arranged downstream of the diffuser layer with respect to the first main radiation direction. The cover foil layer serves to protect the diffuser layer and can also adapt the refractive index to the other medium in order to reduce total reflection.

Finally, in some aspects, the operating element may have an optionally partially transparent colored layer that is downstream of the diffuser layer with respect to the first main radiation direction. The color layer may optionally be structured and, in particular, structured similarly to the structured symbol element. The additional color layer improves the impression of the symbol. In addition, further color impressions can be generated that provide a user with additional information.

In some aspects, converter layers can be provided that convert the light of a first wavelength generated by the optoelectronic components into a second wavelength. In some aspects, these layers are downstream of the diffuser layer, i.e., the emitted light is first homogenized by the diffuser layer and then converted to a second wavelength. In some other aspects, the diffuser layer of the operating element comprises converter particles for converting irradiated light of a first wavelength into light of a second wavelength.

In some further aspects, it may be desirable to further manipulate the light emitted by the optoelectronic components. For this purpose, in some aspects, a color filter may be provided downstream of the diffuser layer with respect to the main emission direction, wherein the color filter is in particular unstructured. For example, the color filter can be used to narrow a broader emission spectrum so that a specific color can be selected from several possible colors. In some aspects, the color filter is adjustable.

In addition to these elements for manipulating emitted light, some embodiments relate to an operating element in which the at least two optoelectronic components are configured to generate light of different wavelengths. For this purpose, components are used that generate different colors, so that not only mixed colors can be generated, but also the operating element can light up in different colors depending on the control, e.g. red or green. In this respect, components of different colors can be arranged close to each other on or in the luminous foil so that the requirements for homogeneity and also the resolution as mentioned above remain guaranteed. Several luminous foils with components of different colors can also be arranged on top of each other to create the desired effect.

For improved stabilization, in some embodiments the operating element comprises a glass layer as a carrier element. Alternatively, the carrier element can also have a carrier foil that is applied to a glass layer. A glass layer is understood here to be any rigid transparent layer. This can include SiO2, but also a rigid and transparent plastic such as Plexiglas or similar.

Some other aspects relate to the design and position of the touch-sensitive sensor. In some aspects, the touch-sensitive sensor is arranged between the luminous foil and the diffuser layer. Alternatively, the touch-sensitive sensor may be arranged downstream of the diffuser layer with respect to the first main radiation direction. In a further alternative embodiment, the touch-sensitive sensor is arranged between the carrier element and the luminous foil. The touch-sensitive sensor can be a capacitive or resistive sensor. In some aspects, the extension can correspond to at least one extension of the structured symbol element. It is therefore possible that the extent of the sensor corresponds to the size of the operating element, but the sensor can also be smaller.

In some aspects, the touch-sensitive sensor can have a large surface area and be reflective, for example with a reflective material. In such an embodiment, the sensor thus also assumes the function of the reflective layer.

Some further aspects relate to the optoelectronic components. For example, the at least two optoelectronic components can be configured as horizontal light-emitting diodes, each with two contact pads on the same side. The contact pads are connected to the terminals of the contact lines. This is expedient, as in this way the emitting side is free of contact pads or other shading. Light may be emitted away from the luminous foil on which the components are arranged. However, another solution is also conceivable in which the components shine through the luminous foil, so they would be arranged on the “underside” of the foil. Alternatively, the at least two optoelectronic components can also be configured as vertical light-emitting diodes, whereby one of the contact lines is guided along an insulated side of the optoelectronic components onto a contact pad, which is located on a light emission side of the optoelectronic component. In another aspect, the two optoelectronic components are surrounded by a transparent material in the main emission direction. The material can be air or another gas, whereby in such a case the optoelectronic components are embedded in a cavity. The surrounding material has a refractive index that is lower than a material of the diffuser layer or an adhesive layer covering the transparent material. This improves the radiation properties. With a suitable choice of materials, light shaping or light guidance can also be achieved so that the light emitted by the optoelectronic components along the first main radiation direction is guided onto the symbol structure.

Another aspect concerns the possibility of designing the operating element in such a way that it can light up in several directions and optionally also be operated. Such an element can be used, for example, for windows, glass doors or the like. In some aspects, the operating element thus comprises a second main radiation direction which is oriented substantially opposite to the first main radiation direction. In addition, the operating element has a second diffuser layer which is arranged downstream of the at least two optoelectronic components with respect to the second main radiation direction. In other words, in the operating element proposed for these aspects, the two optoelectronic components are thus arranged between two diffuser layers. Furthermore, the operating element comprises a structured second symbol element which is not arranged upstream of the second diffuser layer with respect to the second main radiation direction and which is configured to display at least one symbol during operation of the at least two optoelectronic components and a top view of the second diffuser layer along the main radiation direction. In this embodiment, the arrangement of the optoelectronic components is important. For example, the reflective layer can lie in the same plane as the components and also perform electrical or other functions such as heat transport. If, on the other hand, the optoelectronic components are arranged in two different planes, the reflective layer can lie between them so that light scattered back by the respective diffuser layer is reflected by the layer again.

This aspect thus creates an operating element that is illuminated and operable on both sides. It may be useful to arrange the at least two optoelectronic components on different sides of the backlit foil. This allows both sides to be illuminated separately if the luminous foil is reflective or absorbent.

In a further aspect, the structured second symbol element is formed by a second shadow mask arranged behind or on the second diffuser layer with respect to the second main radiation direction. The distance between the second diffuser layer and the at least two optoelectronic components is greater than half the distance between the at least two optoelectronic components. Alternatively, the structured second symbol element can also be formed by the diffuser layer. In such an embodiment, it is thus possible to provide different types of symbols, so that the operating element displays different symbols depending on the viewing direction.

In a further aspect, the operating element comprises a second touch-sensitive sensor, which is configured to detect a touch or pressure exerted along the second main radiation direction and to generate an electrical signal therefrom. With a second touch-sensitive sensor, the operating element can be operated from both sides. For this purpose, it may be provided in some aspects that the first and or second touch-sensitive sensor is arranged between two carrier elements and downstream with respect to the main radiation direction of the respective diffuser layer. The second sensor can also be a capacitive sensor, whereby the strength of a signal change can be used to differentiate which of the two sensors is to respond. This means that the operating element can be used on both sides and it is still possible to distinguish which sensor was activated by pressing or touching the operating element.

Another aspect relates to the design of the operating element in order to facilitate operation and, if necessary, to provide the user with haptic feedback. In some aspects, the operating element comprises a haptic button element which is arranged downstream of the respective diffuser layer with respect to the first and/or second main radiation direction. The haptic button element is used to guide the user to the operating element. For this purpose, the haptic button element can have a curvature on its surface.

In some aspects, the haptic touch element is applied to a carrier foil or a glass layer which is arranged downstream of the respective diffuser layer with respect to the first and/or second main radiation direction.

Another aspect is created with a control panel, in particular for a vehicle, an aircraft, or an automation or industrial application. The control panel comprises a glass element, in particular a pane or a panel, and the operating element according to the proposed principle. According to the invention, the operating element is arranged on the glass element in such a way that the glass element forms the carrier element of the operating element, or the carrier element is intimately connected to the glass element. The operating element thus becomes part of the pane or the glass element. This makes it possible to provide several operating elements on panes, glass surfaces or generally smooth surfaces. In the case of glass surfaces in particular, transparency can be retained as far as possible, resulting in only insignificant shading and improved functionality at the same time.

A further aspect relates to a method for manufacturing an operating element. In such a method, a carrier element and a luminous foil are provided. At least two optoelectronic components and contact lines connected thereto are arranged in or on the luminous foil. The at least two optoelectronic components in one mode are configured to generate light along a first main radiation direction. According to the proposed principle, a luminous foil is arranged on the carrier element. Likewise, a diffuser layer is applied to the luminous foil so that light emitted by the at least two optoelectronic components in an operation along the first main radiation direction radiates through the diffuser layer. A distance between the diffuser layer and the at least two optoelectronic components is set such that it depends on a distance between the at least two optoelectronic components.

Likewise, according to the proposed principle, a reflective layer is formed on the side of the luminous foil facing away from the symbol element. Finally, a structured symbol element is provided and is not arranged in front of the diffuser layer with respect to the first main radiation direction. The structured symbol element is configured to display at least one symbol along the first main radiation direction when the at least two optoelectronic components are in operation and a top view of the diffuser layer is taken.

Finally, the method according to the proposed principle comprises arranging a touch-sensitive sensor configured to detect a touch or pressure exerted along or opposite to the first main radiation direction and to generate an electrical signal therefrom.

The process is used to create an operating element that is flexible thanks to the foils used and can therefore be used for a wide range of applications. In some aspects, the diffuser layer is applied to the luminous foil by means of an adhesive layer and attached to it. The thickness of the adhesive layer is selected such that the distance between the diffuser layer and two adjacent optoelectronic components, which are associated with the symbol, is greater than half the distance between the at least two optoelectronic components. On the other hand, the distance between the diffuser layer and two neighboring optoelectronic components that are assigned to different symbols is less than half the distance between the two neighboring optoelectronic components.

The structured symbol element can be formed by a shadow mask arranged on the diffuser layer with respect to the first main radiation direction. Alternatively, the structured symbol element may be formed by the diffuser layer itself. In some further aspects, it is proposed to provide a reflective or absorbing element on a side facing away from the first main radiation direction. In particular, this can be an absorbing paint layer on the carrier element or the luminous foil. Alternatively, the carrier element or the luminous foil can also be formed with absorber particles on the side facing away from the first main radiation direction. This prevents waveguiding of emitted light in the operating element or along the boundary layers towards an external medium.

The luminous foil can be bonded to the carrier element by means of an adhesive layer. It is also possible to provide a cover foil layer to protect against damage or to adjust the refractive index. The cover foil layer is positioned downstream of the diffuser layer with regard to the main radiation direction. An optionally partially transparent colored layer can also be applied, which is arranged downstream of the diffuser layer with respect to the main radiation direction, whereby the colored layer is optionally structured and in particular structured in a similar way to the structured symbol element. All of these measures can improve a user's visual impression.

In some aspects, the touch-sensitive sensor can be arranged between the luminous foil and the diffuser layer. It is also possible to arrange the touch-sensitive sensor downstream of the diffuser layer with respect to the first main radiation direction. In an alternative embodiment, the touch-sensitive sensor is arranged between the carrier element and the luminous foil.

A further aspect is the possibility of emitting light in two opposite directions and thus creating an operating element that is visible from two sides and can also be operated. For this purpose, in some aspects of the method it is provided that one of the at least two optoelectronic components is configured to emit light in a second main emission direction which is oriented essentially in the opposite direction to the first main emission direction. The method now further comprises arranging a second diffuser layer which is arranged downstream of the at least two optoelectronic components with respect to the second main emission direction. Furthermore, a structured second symbol element is formed which is not arranged upstream of the second diffuser layer respect to the second main radiation direction. This is used to display at least one symbol along the main radiation direction during operation of at least one of the at least two optoelectronic components and a top view of the second diffuser layer.

In some aspects, the structured second symbol element is formed by a second shadow mask arranged on the second diffuser layer with respect to the second main radiation direction. The distance between the second diffuser layer and the at least two optoelectronic components is greater than half of the distance between the at least two optoelectronic components. In addition, the structured second symbol element can be formed by the diffuser layer, in particular by a spatially inhomogeneous distribution of diffuser particles.

In some aspects, a second touch-sensitive sensor configured to detect a touch or pressure exerted along the second main radiation direction and to generate an electrical signal therefrom can be arranged to generate an operating element that can be used on both sides.

The first and or second touch-sensitive sensor can be arranged between two carrier elements and downstream with respect to the main radiation direction of the respective diffuser layer. Likewise, a haptic sensing element can be arranged in such a way that it is arranged downstream with respect to the first and/or second main radiation direction of the respective diffuser layer.

### BRIEF DESCRIPTION OF THE DRAWING

Further aspects and embodiments according to the proposed principle will become apparent with reference to the various embodiments and examples described in detail in connection with the accompanying drawings.

FIG. 1 shows a first embodiment of an operating element with some aspects according to the proposed principle;

FIGS. 2A and 2B show different aspects of the proposed principle, here the representation of a shadow mask and the distance relationship between optoelectronic components and diffuser layer;

FIGS. 3A, 3B and 3C illustrate various embodiments of optoelectronic components arranged on a layer for generating the luminous foil according to some aspects of the proposed principle;

FIG. 4 shows a second embodiment of an operating element with some aspects according to the proposed principle;

FIGS. 5A and 5B illustrate various aspects of the proposed principle, in this case the representation of a shadow mask and the distance relationship between optoelectronic components and the diffuser layer;

FIG. 6 shows a third embodiment of an operating element with some aspects according to the proposed principle;

FIG. 7 shows a fourth embodiment of an operating element with some aspects according to the proposed principle;

FIGS. 8A and 8B illustrate a fifth and sixth embodiment of an operating element with some aspects according to the proposed principle;

FIGS. 9A and 9B show a seventh and eighth embodiment of an operating element to illustrate some aspects of the proposed principle;

FIGS. 10A and 10B are illustrations of a ninth and 10th embodiment of an operating element with some aspects according to the proposed principle;

FIGS. 11A and 11B show a 11th and twelfth embodiment of an operating element to illustrate some aspects of the proposed principle;

FIGS. 12A and 12B illustrate a 13th and 14th embodiment of an operating element with some aspects according to the proposed principle;

FIGS. 13A and 13B are illustrations of a 15th and 16th embodiment of an operating element with some aspects according to the proposed principle;

FIGS. 14A and 14B show a 17th and 18th embodiment of an operating element with some aspects according to the proposed principle;

FIGS. 15A and 15B show embodiments of an operating element with some aspects according to the proposed principle, in which light is emitted in two opposite directions;

FIGS. 16A and 16B illustrate a 20th and 21st embodiment of an operating element with some aspects according to the proposed principle;

FIG. 17 shows a further embodiment of an operating element with some aspects according to the proposed principle;

FIG. 18 shows a version of an operating element in various operating states to illustrate some aspects of the proposed principle;

FIG. 19 is an embodiment of a control panel with some aspects according to the proposed principle;

FIG. 20 is an illustration of an example of a method for manufacturing an operating element with some aspects of the proposed principle;

FIG. 21 shows another example of a method to explain some aspects.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that minor deviations from the ideal shape may occur in practice without, however, contradicting the inventive concept. In this context, it is particularly possible to implement the reflective layer as part of individual other layers or as a separate foil to be introduced. In the examples, this is implemented at various positions, although these can be combined with the other aspects of the embodiments shown.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. Thus, it is possible to derive such relationships between the elements based on the figures. However, the proposed principle is not limited to this, but various optoelectronic components with different sizes and also functionality can be used in the invention. In the embodiments, elements with the same or similar effects are shown with the same reference signs.

Nowadays, many applications require display and operating elements to be provided on transparent surfaces. The focus here is on making optimum use of the available space without obstructing the user's view through the transparent surface of a windshield, for example. Roof consoles in the automotive sector are a typical example of display and operating elements in the area of such transparent surfaces. In aircraft construction, in automation and industrial technology as well as in various home appliances or for consumer electronics, it is also practical to arrange display and operating elements on transparent surfaces. However, the currently common design of such display and operating elements leads to an impairment of the field of vision, as mainly non-transparent components are used. In addition, the design options are also limited, as the display and operating elements usually follow fixed shapes.

The inventors have set themselves the goal of realizing cost-effective and partially transparent and filigree display elements so that these can also be used on transparent surfaces without the disadvantages listed above. At the same time, the disadvantages that occur with so-called transparent displays are to be avoided. These include the complex control by means of a TFT pipeline or control electronics and often the optoelectronic components, which are superfluous depending on the display and operating elements and are therefore not required. Nevertheless, due to the various possible applications mentioned above, it is necessary to keep the operating element flexible so that it can be applied not only to smooth and straight transparent surfaces, but also to curved surfaces, for example.

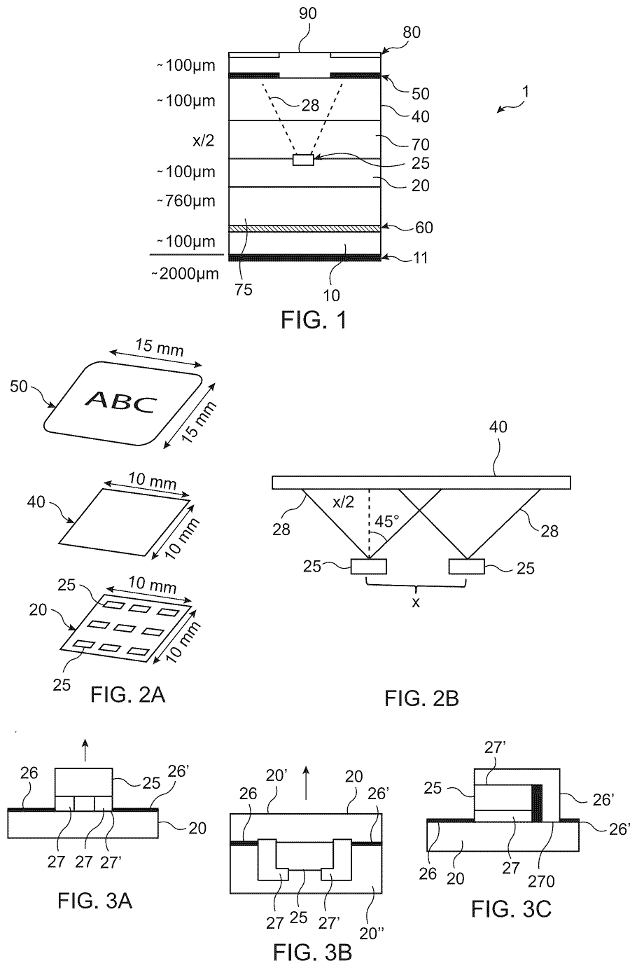

The inventors therefore propose, among other things, an embodiment of an optical display and operating element as shown in FIG. 1. This contains some exemplary aspects of the proposed principle, which are explained in more detail in the other embodiments and can also be combined in various ways. This allows the requirements of the respective field of application to be taken into account.

The embodiment of FIG. 1 comprises a carrier foil 10 which is flexible and made, for example, from a plastic such as PET, PP, PE or another material. The plastic can be transparent. In the present example, a touch-sensitive sensor 60 is applied to the carrier foil 10. The sensor 60 extends over the entire lateral extent of the optical display and operating element and comprises a capacitively reacting sensor element together with its supply and control lines. The touch-sensitive sensor 60 can be significantly thinner than the carrier foil as shown, so that the stability is essentially achieved by the carrier foil 10. An adhesive layer 75 is now applied to the touch-sensitive sensor, which connects the touch-sensitive sensor on the carrier foil 10 to an illuminated foil 20. The illuminated foil 20 comprises one or more optoelectronic components 25 together with their control and supply lines. The control and supply lines are omitted here for the sake of clarity.

In the present embodiment, the optoelectronic components 25 are arranged on the surface of the luminous foil 20 and, in particular, on the side of the luminous foil 20 facing away from the adhesive layer 75. In an alternative embodiment, these optoelectronic components can also be provided in the luminous foil 20, so that the luminous foil 20 surrounds the optoelectronic components 25. For this purpose, it is conceivable to produce the luminous foil 20 separately and, for example, to build it up from several sublayers. These are arranged on top of each other so that the optoelectronic components 25 are arranged between different sub-layers of the luminous foil 20.

The optoelectronic components 25 in or on the luminous foil 20 have a main radiation direction 28. The main radiation direction is defined by the direction of the light emitted by the optoelectronic components during operation. The luminous foil 20 is bonded to a diffuser layer 40 by means of an adhesive layer 70. Diffusor layer 40 contains diffusor particles that scatter the light emitted by the optoelectronic components 25 and thus distribute it homogeneously. In the present embodiment example, a structured mask 50 is applied to the diffuser layer 40 as a symbol element, over which in turn a protective foil 90 is arranged. Optionally, a further structured colored layer 80 can be arranged on the protective foil 90.

PET or another transparent plastic described in this application is used as the material for the individual foil layers. In addition to other adhesives, PVB or EVA can also be used as material for the adhesive layer.

During operation of the present operating element, the optoelectronic components 25 generate light and emit it along the main emission direction 28 in the direction of the diffuser layer 40. In the diffuser layer 40, the emitted light is distributed as evenly as possible and then falls on the shadow mask 50, so that a user can recognize one or more symbols when looking at the optoelectronic components.

The different materials can also result in total reflection within the layer sequence, so that the light is reflected back and, in particular, radiated away in the direction of the carrier foil 10. For this reason, a reflective layer 11 is applied to the carrier foil 10, which again reflects the light scattered back in the diffuser layer. The inventors have recognized that the proportion of light scattered back through the diffuser layer is quite large. Therefore, the reflective layer 11 significantly improves the light extraction through the mask 50 and thus increases the intensity of the emitted light.

In this embodiment, the reflective layer is applied to the rear of the carrier 10, for example as a metallic mirror. This type of production is particularly simple as the reflective carrier serves both as a carrier and as a reflective layer. However, the reflective layer can also be configured independently of the carrier as a separate reflective foil and bonded to the carrier.

FIGS. 2A and 2B show some further aspects of the proposed principle, in particular to explain the corresponding dimensions. In the present partial FIG. 2A, it is shown that the display and operating element has approximately a dimension of 15×15 mm. The mask 50 therefore has approximately the same dimensions and, as shown here, displays a character string ABC, which is formed by cut-outs in the shadow mask. The diffuser layer 40, on the other hand, is somewhat smaller and is arranged centrally below the shadow mask 50. In particular, the diffuser layer 40 thus lies above the exposed surfaces of the shadow mask and the symbols A, B and C shown.

A pixel matrix consisting of 3×3 optoelectronic components 25 is now provided as part of the illuminated foil 20 to ensure the most homogeneous illumination possible. During operation, this pixel matrix generates light of a predetermined wavelength, which falls through the diffuser layer 40 homogeneously and from below onto the shadow mask. For a user, this results in a uniformly illuminated symbol sequence ABC. In this design example, components 25 of the same color are used. However, it is also possible to use components of different colors to generate different colors. These can illuminate different symbols, for example.

FIG. 2B shows some aspects of dimensioning the display and operating element according to the proposed principle. Two neighboring optoelectronic components are shown, which have a distance to each other, which is also referred to as the pixel pitch. In order to achieve homogeneous illumination of the symbols A, B and C in the shadow mask 50, it is advantageous that the light emitted by the optoelectronic components overlaps before it falls on the diffuser layer 40.

Otherwise, there is a risk that there is also insufficient light distribution and homogenization in the diffuser layer 40, so that a user perceives a different light distribution and possibly even the individual electronic components 25 when looking at the display and operating element from above across the symbols. To prevent this, it is useful for the spacing of the optoelectronic components 25 to have a certain dependence on the pixel pitch at a specified aperture angle of 45°, for example.

As shown in sub-FIG. 2B, the two light cones emitted by the optoelectronic components overlap along the main emission direction 28 if the distance between the electronic components 25 and the diffuser layer is approximately half the pixel pitch x. If the distance between the optoelectronic components 25 and the diffuser layer 40 is greater, the overlap of the respective light cones along the main emission direction 28 also increases and the homogenization by the diffuser layer 40 is improved.

In order to achieve the necessary distance between the optoelectronic components 25 and the diffuser layer 40, it is proposed according to the invention to design the thickness of the adhesive layer 70 accordingly. The distance between the optoelectronic components on the surface of the luminous foil 20 is thus essentially determined by the thickness of the adhesive layer 70. If the diffuser layer 40 is thicker, an overlap can also take place within the diffuser layer so that homogenization is ensured.

Several embodiments and designs are conceivable for producing electronic components on the backlit foil 20. FIG. 3 shows in its partial figures A, B and C various possible designs for the arrangement of optoelectronic components 25 on or in the luminous foil.

Partial FIG. 3A shows the arrangement of an optoelectronic component 25 as a horizontal light-emitting diode on the luminous foil. The luminous foil 20 comprises several supply lines 26 and 26′, which lead to contact pads or connections 27 and 27′. The optoelectronic component 25 is configured as a horizontal light-emitting diode, so that the two contact pads 27, 27′ are arranged on a side of the optoelectronic component 25 opposite the main radiation direction. The optoelectronic component 25 is arranged with its two contacts 27 and 27′ on the connections of the luminous foil and intimately connected to these by means of solders or other methods. In this embodiment, the optoelectronic component 25 lies directly on the luminous foil 20 and can be surrounded by a transparent material, for example the adhesive layer 70, in the further course.

FIG. 3B shows an embodiment in which the optoelectronic component 25 is integrated into the luminous foil. For this purpose, the luminous foil 20 comprises a first sublayer 20′ on which the leads 26 and 26′ are arranged on one side. The light-emitting side of the optoelectronic component is now applied to the sublayer 20′. The leads 26 and 26′ are connected to the underside of the optoelectronic component 25 by means of a solder or another metallic contact. As shown in sub-FIG. 3B, the two contact lines at least partially enclose the component on at least two sides and contact the connection pads 27 and 27′ on the side of the optoelectronic component opposite the sub-layer 20′. A second sublayer 20″ is then applied, which encapsulates and completely surrounds the optoelectronic component. The two sub-layers 20′ and 20″ thus completely embed the optoelectronic component 25 in the luminous foil 20.

In contrast, sub-FIG. 3C shows an embodiment with an optoelectronic component as a vertical light-emitting diode. In contrast to horizontal light-emitting diodes as in sub-FIGS. 3A and 3B, the contact pads 27 and 27′ of vertical light-emitting diodes are arranged on opposite sides and surfaces of the component 25. In FIG. 3C, the optoelectronic component 25 is guided with its contact pad 27 to a terminal and connected to it. Contact pad 27 thus contacts the supply lines 26 on the illuminated foil 20. A further connection line 26′ is routed via an externally arranged feed to the upper side and thus the light-emitting side of the optoelectronic component 25 and connected to the contact pad 27′. In order to avoid shading and thus a reduction in the intensity of the emitted light, the feed 26′ on the top side of the optoelectronic component is transparent. For example, ITO or other suitable materials can be used for this purpose. To prevent a short circuit, insulation 270 is also arranged on the side wall along which the feed runs. This prevents a short circuit between the feed line 26 and, for example, the further contact pad 27 or the individual semiconductor layers of the optoelectronic component.

In the embodiments shown in sub-FIGS. 3A) and 3B), in some aspects the supply lines to the connections 26 and 26′ can be configured as flat metallic and thus reflective supply lines. As a result, in addition to the electrical function, these also assume the function of a reflective layer. In other words, the reflective layer in these embodiments is essentially arranged in the plane of the optoelectronic component. Such an arrangement has the advantage that the component can radiate to both sides and the reflective layer reflects backscattered light from both sides.

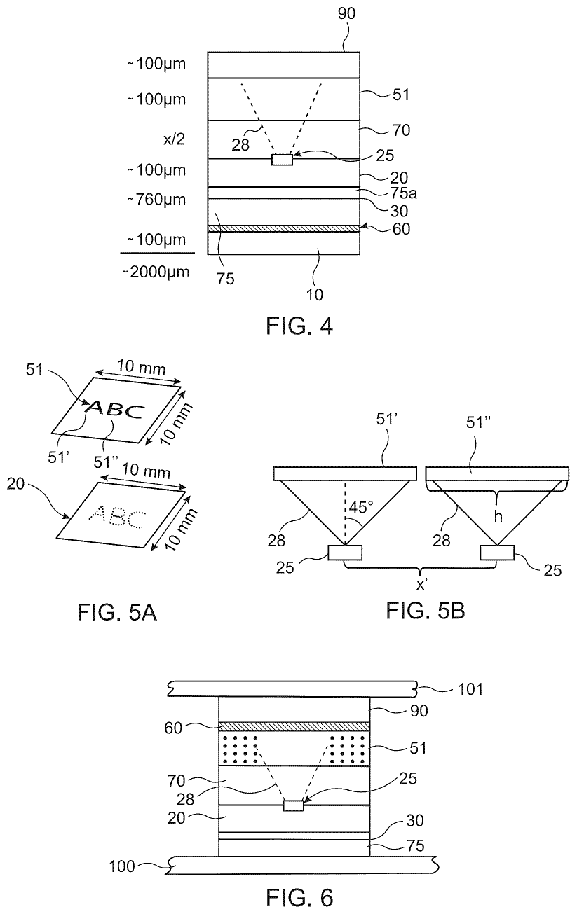

In addition to using a mask, it is also possible to structure the diffuser layer, which is illuminated by the light from the component, in a suitable manner and thus create the desired symbol element. FIG. 4 shows a corresponding embodiment to illustrate this principle. Structures with the same function or effect bear the same reference symbols.

The display and operating element of FIG. 4 again comprises a flexible carrier foil 10 with a touch-sensitive sensor 60 arranged on it, which is attached to the illuminated foil 20 by means of an adhesive layer 75. A large number of optoelectronic components 25 with their respective supply lines are arranged in or on the illuminated foil 20. To simplify the illustration, only one optoelectronic component is shown here with the corresponding emission direction 28. The luminous foil 20 is connected to the structured diffuser layer 51 via a further adhesive layer 70. A cover layer 90 is applied to the structured diffuser layer 51.

A reflective layer is inserted between the luminous foil 20 and in the adhesive layer 75. In other words, the reflective layer 30 is embedded here between adhesive layers 75 and 75a, and is thus attached to the sensor 60 and the luminous foil 20.

The diffuser layer is structured via a spatially inhomogeneous distribution of diffuser particles within the diffuser layer. Alternatively, absorber particles can also be arranged in the diffuser layer, which in turn are distributed inhomogeneously, so that the desired symbol appears to a user as a negative by absorbing light. The symbols would light up here, the absorber particles absorb light outside the symbols. The further covering layer 80 serves to adapt the various refractive indices to the surrounding medium and in particular to air, so that total reflection back into the various layers of the display and operating element is avoided or reduced.

Sub-FIGS. 5A and 5B show aspects of the optical display and operating element on the transparent surface to illustrate the principle. As shown, the symbols are also generated here in the form of a character string ABC by the structured diffuser 51. On the one hand, the best possible homogenization of each individual symbol A, B and C should be achieved. On the other hand, it should also be ensured that a user can separate the different symbols from each other, i.e. A and B, for example. Accordingly, the distance between the optoelectronic components must be selected in a suitable manner.

As shown in FIG. 5A, the illuminated foil 20 comprises a large number of individual optoelectronic components, each of which in turn roughly reproduces the individual symbols. This aspect alone already creates advantages because, in contrast to a normal matrix in rows and columns, the optoelectronic components already approximately reproduce the symbols to be displayed later.

Neighboring components, which are therefore assigned to the same symbol, for example symbol A, should therefore be at a distance from each other that ensures the most homogeneous light distribution possible. For example, the distance between the components and the diffuser layer can be selected using the pixel pitch x, as already explained in FIG. 2B. Such a distance enables an overlap of light from the optoelectronic components assigned to the same symbol and thus produces a homogeneous light distribution for this symbol.

FIG. 5B shows the second case, in which two neighboring optoelectronic components 25 are assigned to different symbols, for example symbols A and B. In such a case, the distance between the two optoelectronic components x′ must be selected such that there is precisely no overlap, since otherwise a user may no longer be able to resolve or distinguish the two symbols in the structured diffuser layer 51. In other words, the pixel pitch x′ between the two neighboring optoelectronic components 25, which are assigned to different symbols, is greater than approximately half of the area 51′ or 51″ of the respective symbol to be illuminated. In other words, the distance between the structured diffuser layer 51′ or 51″ to the optoelectronic components is smaller than half the pixel pitch x′ of the two neighboring optoelectronic components 25.

In this way, flexible display and operating elements can be created in which the respective symbols are generated either by a suitable shadow mask or by an inhomogeneous distribution of diffuser or absorber particles within a diffuser layer. The additional covering layer 90 serves on the one hand to protect the underlying diffuser layer 51 or the shadow mask 50 and can also assume the function of adapting the refractive index to the surrounding medium. This reduces the probability of total reflection of emitted light back into the display and operating element. The thickness dimensions shown in FIGS. 1 and 4 are to be understood as examples and can vary depending on the application. In particular, the adhesive layer 75 can also be thinner and thus further reduce the thickness of the entire component. This makes it possible to arrange components between different glass layers and thus integrate them into a pane or similar.

FIG. 6 shows such an embodiment. In this embodiment, a first glass layer 100 simultaneously forms the carrier element 10 for the optical display and operating element. An adhesive layer 75 is applied to the glass layer 100, which bonds the glass layer to the backlit foil 20. Several components 25 are integrated in the illuminated foil 20 and generate light along the main radiation direction 28 during operation. This light is coupled into a structured diffuser layer 51 via a hot-melt adhesive layer 70 and generates one or more symbols there when a user looks at the optical display element from above.

The structured diffuser layer 51 is configured here with absorber particles that absorb the light emitted by the optoelectronic components 25. The absorber particles in the diffuser layer 51 thus form a negative for the symbols to be displayed. Above the structured diffuser layer 51, a transparent touch-sensitive sensor element 60 is arranged, which is protected by a cover layer 90. A glass pane 101 is again applied to the cover layer 90 and intimately connected to it. Here too, the reflective layer 30 is attached to the carrier foil 20 in the form of a thin metal foil.

In the embodiment shown in FIG. 6, several changes have been made compared to the previous embodiments, each of which can also be combined with the other embodiments. Firstly, this concerns the arrangement of the touch-sensitive sensor element 60 within the optical display and operating element. While, in contrast to the previous embodiments, the touch-sensitive sensor element 60 is arranged outside the main beam direction, in the embodiment of FIG. 6 it is located above the structured diffuser layer 51. It is thus arranged in the main beam direction of the light and, in particular, downstream of the diffuser layer 51 with respect to the main beam direction. A user touching the glass layer 101 in the area above the structured diffuser layer can thus be detected by the sensor 60 and a signal generated therefrom. A second aspect relates to the arrangement of absorber particles in the structured diffuser layer 51, which acts as a negative and is configured similarly to the shadow mask. The spatial distribution of the absorber particles is inhomogeneous, so that different symbols can be realized. Finally, the carrier element is configured here directly as a glass layer 100, so that the overall thickness of the optical display and operating element is reduced.

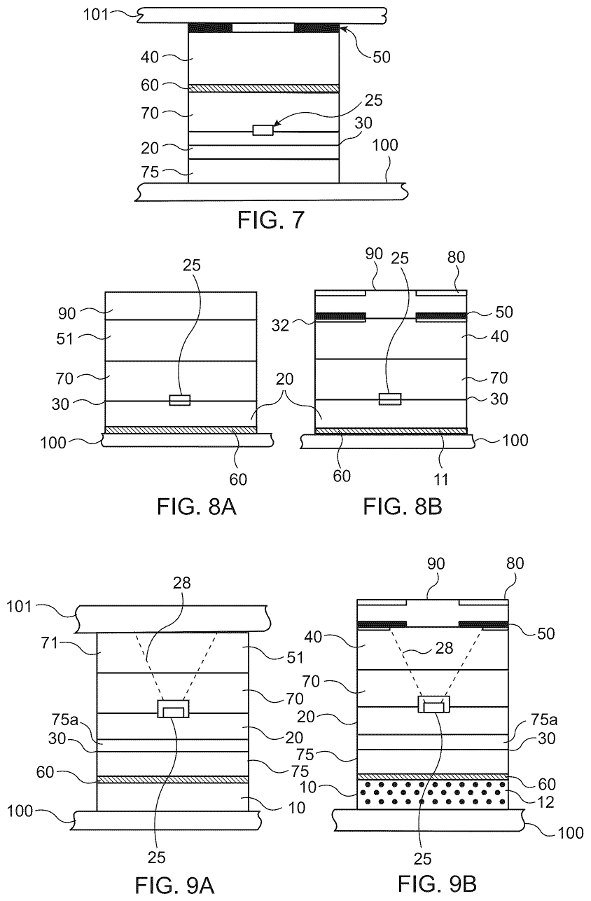

FIG. 7 shows a further embodiment that is similar to the embodiment in FIG. 6. In contrast to the structured diffuser layer 51 used in the embodiment of FIG. 6, a shadow mask 50 is applied directly to the diffuser layer 40, which is unstructured per se. The shadow mask is covered by a glass layer 101, which protects the shadow mask 50 and the underlying diffuser structure 40. In contrast to FIG. 6, the touch-sensitive sensor is arranged between the adhesive layer 70 and the diffuser layer 40. The operating element shown in FIG. 7 is thus inserted and fixed between the two glass layers 100 and 101. Another difference is that the reflective layer 30 is embedded in the carrier foil 20. This already takes place during manufacture, in which the carrier foil 20 is produced as a composite of transparent partial foils and a reflective layer 30 embedded therein.

In the area of windshield or glass panels, the display and operating element can thus be arranged between the two individual panes according to the proposed principle. In this respect, the display and operating element can be used as part of a connecting structure between the two individual panes to form a complete windshield or panoramic windshield. The display and operating element according to the proposed principle can always be provided between the panes in the connecting layer of composite panes.

FIGS. 8A and 8B show further aspects of the proposed principle. In sub-FIG. 8A, the touch-sensitive sensor 60 is applied directly to the glass pane 100 as a carrier element and then the luminous foil 20 is arranged directly on top of it. The reflective layer 30 is located in the plane of the optoelectronic components, surrounds them and is therefore located in front of the touch sensor. In this way, the design and shape of the sensor 60 has no effect on the reflection behavior and thus the intensity of the emitted light. Furthermore, the reflective layer can be in electrical contact with the component and thus partially form a contact. Alternatively, it is also insulated from it, but arranged close enough to ensure sufficient heat transfer, which cools the component during operation. An adhesive layer 70 is applied between the luminous foil 20 and the optoelectronic components 25 located thereon, which bonds the luminous foil 20 to the structured diffuser layer 51. The cover foil layer 90 is bonded to the diffuser layer 51. FIG. 8B shows a similar embodiment. In contrast to sub-FIG. 8A, an absorbent paint layer 11 is applied to the carrier element 100. The touch-sensitive sensor 60 is again arranged on this layer.

Instead of the structured diffuser layer 51 in FIG. 8A, a diffuser layer 40 made of an unstructured material is used in sub-FIG. 8B. To generate symbols, the shadow mask 50 is arranged on the diffuser layer 40, which in turn is followed by a cover foil layer 90 and a structured color layer 80. A second reflective layer 32 is now applied to the underside of the shadow mask 50. This is produced together with the shadow mask, with one side being absorbent and the other side forming the reflective layer 32. Alternatively, two foils can also be applied to each other as layer 32 and mask 50 and bonded together.

FIGS. 9A and 9B disclose further combinable aspects of the proposed principle. In sub-FIG. 9A, a display and operating element is shown which is inserted between two glass panes 100 and 101. The display and operating element comprises a flexible carrier foil 10 with a touch-sensitive sensor 60 applied thereto, an adhesive layer 75, the reflective layer 30, a further thin adhesive layer 75a and an illuminated foil 20 arranged thereon and connected thereto. One or more optoelectronic components 25 are in turn arranged on the illuminated foil 20. As shown, the components are surrounded only by a further medium 71, which has a lower refractive index than the adhesive layer 70.

The shape of the further medium or material 71 can be configured to run out in the edge area of the optoelectronic components, with the medium 71 also running parallel along or parallel to the light-emitting surface of the optoelectronic components in particular. In some embodiments, the component can thus be arranged in a depression or recess in the layer 70. In embodiments in which the components 25 are implemented within the luminous foil, they may be arranged within a recess in the luminous foil 20.

For example, it is possible to design the luminous foil 20 with several layers, as in one of the previous examples, with the optoelectronic components each being arranged in a recess within one of these sub-layers. Each component can be arranged in a separate recess, or several components can be arranged in a common recess. The recess is larger than the optoelectronic component or components themselves, so that there is a gap between the light-emitting surface and a subsequent layer of material. This gap is filled with gas, which has a lower refractive index than the surrounding material. The surrounding medium with the low refractive index reduces total reflection of emitted light and at the same time improves guidance along the desired main radiation direction into the adhesive layer 70 or overlying layers.

The adhesive layer 70 further connects the luminous foil 20 to the structured diffuser layer 51 to generate one or more symbols.

In contrast, FIG. 9B shows a slightly different embodiment in which the corresponding symbols are not conveyed to a user by structuring the diffuser layer 51, but by means of a shadow mask 50 applied to the unstructured diffuser layer 40. A cover foil layer 90 with a colored layer 80 incorporated therein is again formed over the shadow mask 50. Although this covers the underside of the shadow mask, a small area is also left blank around the opening in the mask 50. The area of the layer 33 is therefore slightly smaller than the surface of the mask 50. The recess around the opening improves the radiation behavior.

Furthermore, reflector particles 12 are incorporated into the carrier foil layer 10, which in this way forms the function of the reflective layer. Depending on the embodiment, the reflector particles can also be incorporated in the foil layer 20 below, i.e. opposite to the main radiation direction of the optoelectronic components 50. It is also possible to provide the reflector particles in the adhesive layer 75. In this respect, it should be mentioned that the diffuser layer has proven to be sufficient for reducing light wave conduction within the display and operating element.

SubFIGS. 10A and 10B show a further embodiment of a display and operating element according to the proposed principle, in which a color filter 95 is also arranged above the unstructured diffuser layer 40 or the structured diffuser layer 51. The color filter 95 is used to manipulate the emission spectrum of light emitted by the optoelectronic components 25 arranged below the color layer 95. If these emit a very broadband emission spectrum, the color filter 95 allows a specific part of the emission spectrum to be selected. In addition, the color filter 95 can also be configured as an electrochromic filter 95 so that, on the one hand, the emission spectrum can be adjusted and, on the other hand, the shape of the symbols can be suitably configured by the shadow mask 50. In subFIG. 10A, the color filter 95 is arranged between the diffuser layer 40 and the shadow mask 50. Here too, a first reflective layer 30 is arranged in the interface between foil 20 and adhesive layer 75. A further reflective layer 32 is located between the color filter 95 and the shadow mask 50. In this way, light falling on the shadow mask from behind is filtered again, thus improving the radiation behavior.

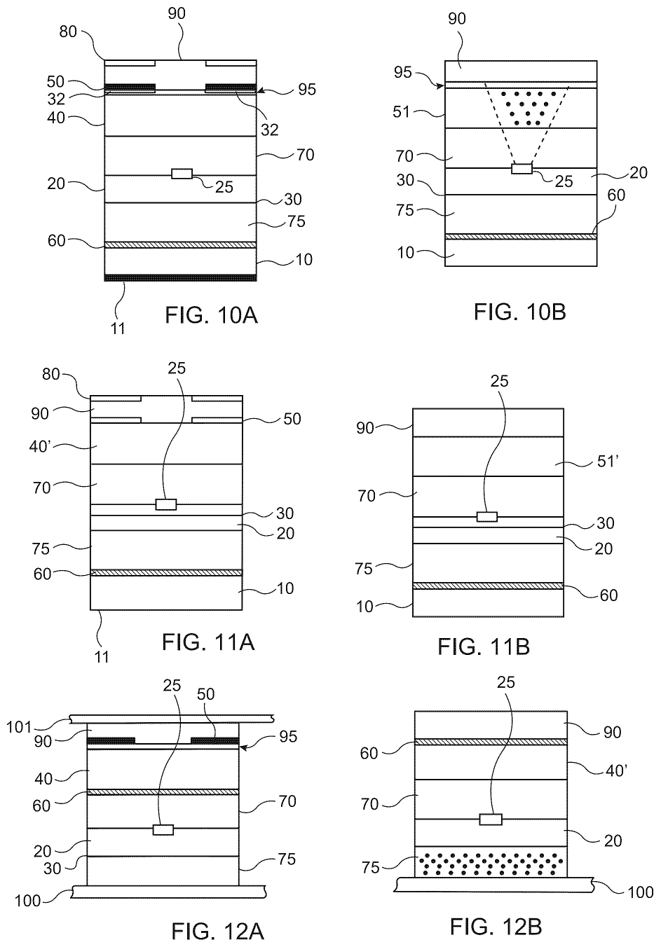

In FIG. 10B, the color filter 95 is applied to the structured diffuser layer 51. Although the color filter 95 can also be implemented between the structured diffuser layer 51 and the adhesive layer 70 in this context, a spatial light intensity is lower due to the diffuser particles within the structured diffuser layer 51. As a result, the color filter 95 in the form shown in FIG. 10B can be somewhat thinner than would be the case, for example, with a color filter between the diffuser layer and the adhesive layer 70.

As in the previous embodiments, the touch-sensitive sensor 60 is applied to the carrier element 10, i.e. the carrier foil. It is thus located behind the main radiation direction of the respective optoelectronic components.

FIG. 11 shows in sub-FIGS. 11A and 11B two further embodiments of a display and operating element, in which the diffuser layer 40 is additionally formed with converter particles. In the partial FIG. 11A, the converter particles are accommodated in the diffuser layer 40 and serve to convert the light of a first wavelength emitted by the optoelectronic components 25 into a second wavelength. In the embodiment example of sub-FIG. 11A, the optoelectronic components 25 generate a blue light during operation, which is converted into yellow light by the converter particles in the diffuser layer 40′. The resulting mixed light has the color white and is displayed in a corresponding symbol for the viewer via the shadow mask 50. The reflective layer, which is located just below the optoelectronic component 25 in the carrier foil 20, is reflective both for blue light and for the converted light.

Partial FIG. 11B shows a similar embodiment in which the diffuser layer 51′ is both structured and filled with converter particles. Depending on the configuration, the converter particles are also spatially inhomogeneously distributed so that light conversion takes place primarily in areas of the symbol to be displayed. In this way, it is possible to create a display and operating element in which the symbol is generated by a different colored structure. For example, the individual symbols can glow white, while the surrounding areas shine with the blue light emitted by the optoelectronic components. Alternatively, it is also possible for the display and operating element to be essentially illuminated in white, with the symbols being displayed to a user by unconverted blue light.

FIG. 12 shows in subFIGS. 12A and 12B a further embodiment in which the position of the touch-sensitive sensor 60 can be adjusted with respect to a color filter layer 95 or a converter layer 40′. The two partial figures thus form combinations of features of the preceding embodiments, in which the touch-sensitive sensor 60 is arranged at different positions within the display and operating element.

In subFIG. 12A, the touch-sensitive sensor 60 is applied between the adhesive layer 70 and the diffuser layer 40. The color filter 95 is arranged above the diffuser layer. In addition, a transparent glass layer 100 is provided in sub-FIG. 12A, to which the display and operating element with its adhesive layer 75 is applied. A further glass layer 101 lies over the cover foil layer 90, so that the individual layers of the display and operating element are embedded between the two glass layers. The reflective layer also forms the interface between the adhesive layer 75 and the carrier foil 20

In partial FIG. 12B, on the other hand, the sensitive sensor 60 is arranged downstream of the converter and diffuser layer 40′ with respect to the main radiation direction, i.e. it is located between the converter layer 40′ and a cover foil layer 90. Also in partial FIG. 12B, a glass layer 100 is provided, to which the adhesive layer 75 with reflector particles is applied to prevent light wave conduction.

It should be mentioned at this point that the individual embodiments, in particular the different layers, can be combined in different ways. As shown in the preceding and following embodiments, the capacitive or resistive touch-sensitive sensor 60 can be provided at different positions within the display and operating element. The sensor 60 can also be configured to be transparent so that, on the one hand, it does not prevent a user from seeing through the glass panes and, on the other hand, light from the optoelectronic components 25 can easily pass through the sensor.

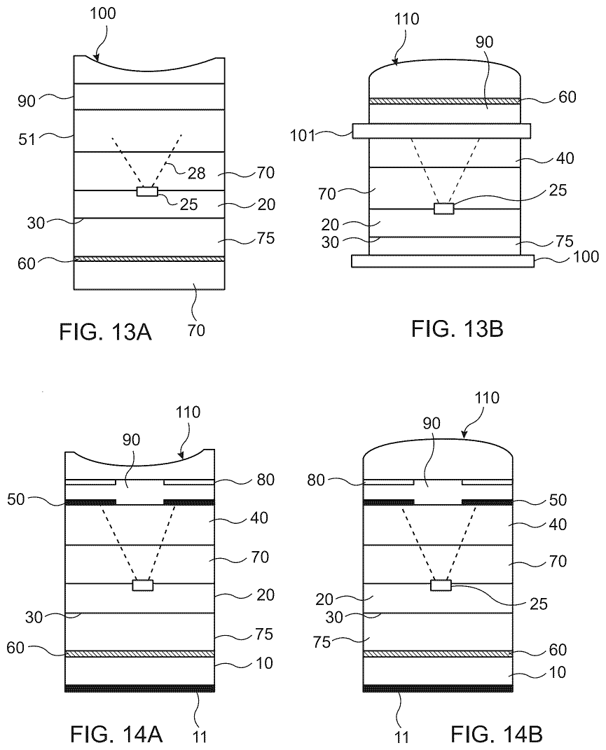

FIGS. 13 and 14 show further embodiments in their respective sub-figures A and B, wherein a haptic button element 110 is additionally provided. The haptic button element 110 is configured differently and serves to provide a user with a haptic indication in addition to a visual indication. As a result, a user can also detect the display and operating element by the haptic indication alone and activate the sensitive sensor by exerting pressure or pressing a button.

In subFIG. 13A, the haptic tactile element 110 is applied directly to the cover foil layer 90. The cover foil layer 90 is in turn connected to the structured diffuser layer 51. In sub-FIG. 13B, individual layers of the display and operating element are arranged between two glass layers 100 and 101. The first cover foil layer 90 of the display and operating element is applied to the side of the glass layer 101 facing away from the optoelectronic components 25. The touch-sensitive sensor 60 is arranged on this. The haptic button element 110 is located directly on the touch-sensitive sensor and is thus arranged in the immediate vicinity of the latter. This embodiment is practical because the display and operating element can be produced separately as a separate display element with the two glass layers 100 and 101. In a subsequent step, the touch-sensitive sensor is then arranged together with the haptic touch element 100 and the cover foil layer 90 on the cover-side glass layer 101 to complete the display and operating element.

FIG. 14 shows a further embodiment, this time with shadow mask 50. The two partial FIGS. 14A and 14B are constructed in a similar manner and essentially correspond to the embodiment of FIG. 1. In both partial figures, the reflective layers 30 are arranged between the interface 20 and the adhesive layers 75. Only two differently curved and shaped haptic tactile elements 110 are applied to the upper side of the cover foil layer 90 and the color layer 80 and attached to them.

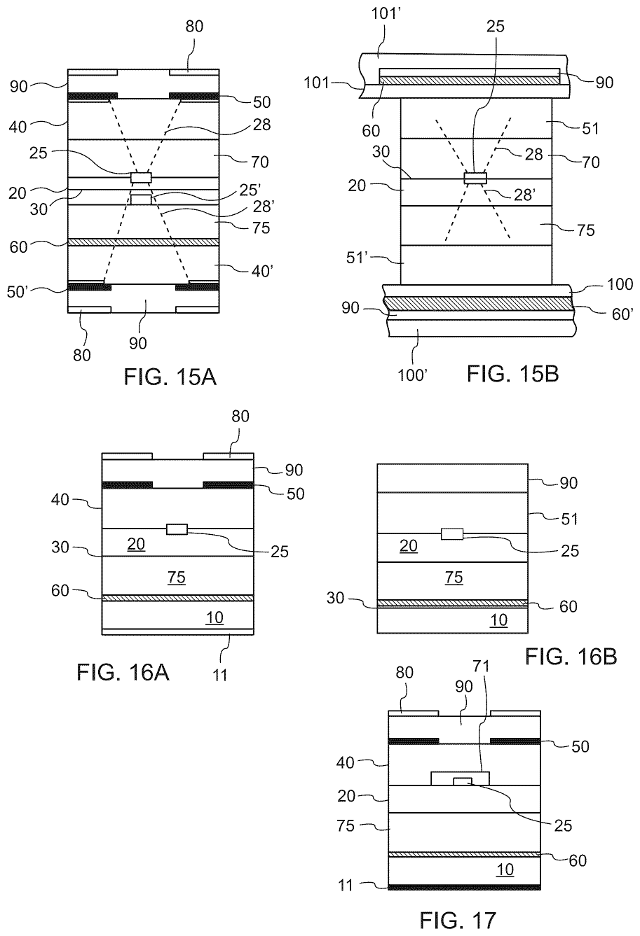

FIG. 15 shows in its partial figures A and B a further different concept of the proposed principle, in which the display and operating element has a further main radiation direction in contrast to the previous embodiments. This second main radiation direction 28′ is opposite to the first main radiation direction 28.

In FIG. 15A, the optical display and operating element with its individual layers is essentially symmetrical, with a central layer 20 being configured as an illuminated foil with several optoelectronic components 25. The optoelectronic components are spaced apart from one another. A first reflective layer 30 is arranged in the plane between the two components 25 and 25′. Furthermore, second reflective layers are provided on the respective rear sides of the shadow masks 50 and 50′ (i.e. the side of the shadow mask facing the components). These are slightly smaller, which exposes the shadow mask around the opening.

The adhesive layer 75, on which the sensitive sensor element 60 is arranged, is provided along the second main radiation direction 28′. A structured diffuser layer 40′ is then applied, which is followed by a second shadow mask 50′. The shadow mask 50′ is in turn covered by the cover foil layer 90 and a similarly structured colored layer 80. The symbol of the second shadow mask 50′ may differ from the symbol of the first shadow mask 50 along the first main radiation direction 28. However, it is also possible that both show the same symbol.

In one operation, the two optoelectronic components 25 and 25′ generate light in the different main radiation directions 28 or 28′. A suitable reflective layer or reflector particles within the luminous foil 20 can prevent crosstalk of light from the upper area, i.e. along the first main radiation direction, which is reflected back into the second area. Conversely, light emitted in the second main radiation direction 28′ cannot reach the area of the first main radiation direction and the shadow mask 50 due to the reflector particles in the luminous foil 20. In this way, the optical display and operating element can be implemented for a double-sided application, whereby the symbols can be controlled differently on both sides of the application.

Sub-FIG. 15B shows a further embodiment of such a principle. In this embodiment, several changes have been made compared to sub-FIG. 15A. Firstly, the shadow mask 50 and 50′ are replaced by structured diffuser layers 51 and 51′, as in the previous embodiments. At the same time, only one type of optoelectronic component 25 is provided, which is configured to emit light both in the first main emission direction 28 and in the second main emission direction 28′ from the luminous foil 20. The reflective layer 30 is arranged in the plane of the optoelectronic component 25, so that the component emits light on both sides, which may be reflected back by the reflective layer 30. The optoelectronic component 25 thus generates light in both directions during operation.

A first glass layer 101 is now applied to the diffuser layer 51′. A touch-sensitive sensor 60 with a subsequent transparent cover layer 90 is arranged on this glass layer. The touch-sensitive sensor and the cover layer 90 are encapsulated together by a further glass layer 101′. A similar structure is located on the second diffuser layer 51′ with a glass layer 100, a touch-sensitive sensor 60′ and a cover layer 90 arranged thereon. This touch-sensitive sensor 60′ with its cover layer 90 is also surrounded by a further glass layer 100′. During operation of this display and operating element, a user can operate the element on both sides using the two touch-sensitive sensors present.

The two touch-sensitive sensors and their readout and control electronics are configured in such a way that they can detect from which side a user touches the optical display and operating element or exerts pressure on it. This can be determined, for example, by the different capacitance changes in the touch-sensitive sensors 60 and 60′. For example, a change in capacitance should be greater in the sensor that is closer to the user's touch point. In this way, an operating element can be embedded in a transparent surface, for example between two panes, and can be operated from both sides.

FIG. 16 shows in its partial figures A and B a further embodiment in which the luminous foil 20 with its optoelectronic components 25 is attached directly and immediately to the diffuser layer 40 or the structured diffuser layer 51. In subFIG. 16A, the optoelectronic components are integrated in the luminous foil 20, the reflective layer 30 is again arranged at the interface between the adhesive layer 75 and the foil 20. The luminous foil 20 and the diffuser layer 40 are bonded together without a further additional adhesive layer. The thickness of the diffuser layer 40 is selected so that the symbols of the shadow mask 50 can still be sufficiently homogeneously illuminated. In part FIG. 16B, the diffuser layer 51 is structured and connected to the illuminated foil 20 in a similar way directly, without any further adhesive layer or only by a very thin adhesive layer. On the side facing away from the main radiation direction, the adhesive layer 75 connects the luminous foil 20 to the touch-sensitive sensor 60. Here, the reflective layer lies directly on the carrier 10 and is also conductive in order to form a connection for the touch sensor 60. This is arranged directly on the layer 30. In this version, layer 30 and sensor 60 form a single unit.

FIG. 17 shows a further embodiment of the proposed principle. In this case, optoelectronic components 25 are arranged on the surface of the luminous foil 20. The diffuser layer 40 now comprises one or more recesses 71 and is positioned in such a way that the component(s) 25 is/are located approximately centrally in the recess 71. A separate recess can be provided for each component 25 or a common recess can be provided for several components. The recess 71 thus forms a cavity in the optical display and operating element, so that the optoelectronic component 25 is surrounded by a medium which has a lower refractive index than the diffuser layer 40. As a result, back reflection can be reduced and the radiation behavior can also be adjusted in a suitable form in the direction of the shadow mask 50. In the embodiment example, the thickness of the diffuser layer 40 is selected such that sufficient homogenization can be set via the symbol generated by the shadow mask 50. Reflective layer 11 is attached to the opposite side of transparent carrier layer 10.

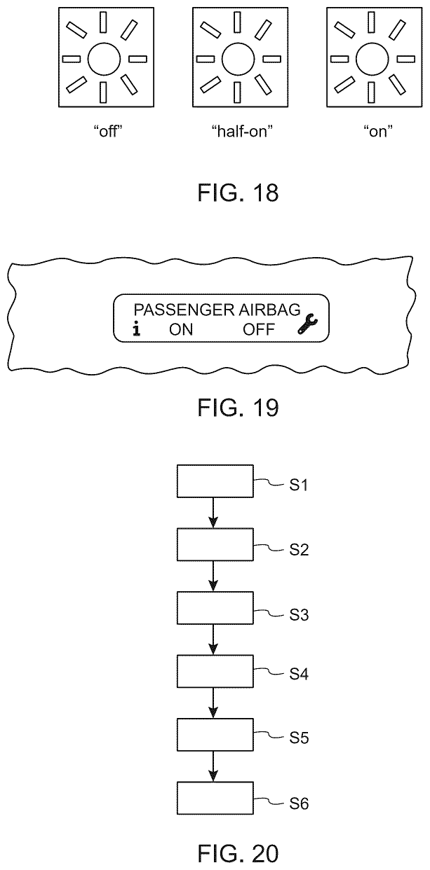

FIG. 18 now shows a possible application of a display and operating element according to the proposed principle. As explained in the previous examples, the display and operating element comprises one or more possible optoelectronic components. In some embodiments, the optoelectronic components form a simple matrix structure in rows and columns, with the homogenization and display of the symbol being performed by a shadow mask as the symbol element. In other embodiments, the arrangement of the optoelectronic components is such that they follow the shape or arrangement of the symbol to be displayed.

FIG. 18 shows an embodiment of a stylized sun as a possible display and operating element. The display and operating element can be switched between three states, which are designated as “off”, “half-on” and “on”. In the first state, “off”, the optoelectronic components are switched off and the symbol is essentially invisible or only visible through its structure or the shadow mask. When the symbol is actuated or external parameters are changed, the state of the display and operating element is switched from the “off” state to the “half-on” state. In this state, it is possible, for example, to activate only half of the respective optoelectronic components in order to generate a low level of illumination.

For example, only the optoelectronic components assigned to the lower half of the sun shown can be switched on. Alternatively, the components can also be operated with less current so that the intensity is lower. When the display and operating element is operated or another external parameter is changed, the display and operating element is switched from the “half-on” state to the “on” state. As a result, all optoelectronic components are activated equally and the symbol is displayed in its full form. Alternatively, the brightness of the symbol can also be changed. The special arrangement of the optoelectronic components under one shape structure of the symbol together with the diffuser layer ensures uniform illumination of the symbol even with different light intensities.

FIG. 19 shows a control panel that can be placed on a windshield or other transparent surface, for example. The control panel shown here comprises several symbols that can be illuminated in different ways and also have different colors in the various states. On the left-hand side, the control panel comprises an operating element with a single symbol, then an operating element with an information display called “Passenger Airbag” with two additional switchable symbols for active activation or deactivation, and on the right-hand side an operating element with a further icon. By pressing the individual symbols, different functions of the operating elements can be called up on a display or in another form and shown if necessary.

It is also possible to change the individual colors when the respective area of the control panel is pressed or to adjust their intensity. In this way, a user is not only informed of which function he is currently performing, but the status of the respective operating element and the function behind it is also displayed. In this way, different display and operating elements can be implemented on windscreens, glass panes or other transparent surfaces. Different colors can be used for the optoelectronic components so that the operation and status are not only indicated to the user by a simple “lit”, “not lit”, but also by different colors. The flexible design using a carrier foil also makes it possible to apply the optical display and operating elements to existing curved or straight surfaces. This increases flexibility and the display and operating elements can also be retrofitted.

Finally, FIG. 20 shows in schematic form the various process steps for manufacturing a display and operating element according to the proposed principle. In step S1, a carrier element is provided. This can be, for example, a flexible carrier foil made of a transparent or non-transparent plastic. In some embodiments, this carrier foil is also filled with reflector particles in order to reflect light back to the diffuser layer. The carrier element can also be the glass pane itself, to which the other elements of the display and operating element are applied at a later stage.

In a second step S2, a luminous foil is now provided, in or on which at least two optoelectronic components and contact lines connected thereto are arranged. The components are configured to generate light of a first and possibly also a further wavelength along a first main radiation direction. As explained in the previous examples, such a luminous foil can be prefabricated, whereby the optoelectronic components can be integrated either on the surface of the luminous foil or in it. In the latter case, the luminous foil is formed by several partial layers that are arranged on top of each other and enclose the optoelectronic components on both sides.

In step S3, the luminous foil is applied to the carrier element and attached to it. For this purpose, an adhesive layer can be used in a suitable manner, which is arranged between the carrier element and the luminous foil. However, it is also possible to arrange the luminous foil directly on the carrier element without a further adhesive layer and to attach it to the carrier element by means of pressure and heat, among other things.

A diffuser layer is then arranged on the luminous foil in step S4 so that the light emitted by the optoelectronic components reaches the diffuser layer. The diffuser layer is arranged on the luminous foil in such a way that sufficient homogenization of the emitted light is achieved. For this purpose, for example, an additional adhesive layer can be provided between the diffuser layer and the luminous foil, the thickness of which can be adjusted in a suitable manner. A possible distance between neighboring optoelectronic components, the pixel pitch, creates a dependence on the thickness of the corresponding adhesive layer or the distance between the optoelectronic components and the light-emitting side of the diffuser layer. The thickness of the diffuser layer and the thickness of the adhesive layer are selected in such a way that the light emitted by the optoelectronic components overlaps and thus achieves sufficient homogenization when it enters the diffuser layer, or at the latest when it exits the diffuser layer, to give the user the impression of a uniform and homogeneous light distribution.

In step S5, a structured symbol element is now provided, which is not arranged in front of the diffuser layer with respect to the main radiation direction. The symbol element is configured to display at least one symbol along the first main radiation direction during operation of at least one of the at least two optoelectronic components and during a top view of the diffuser layer by a user. The structured symbol element can thus depict one or more symbols, characters or letters.

In a final step S6, a touch-sensitive sensor is provided. This is configured to recognize and detect an exerted touch or pressure either along the first main radiation direction or opposite to it and to generate an electrical signal from this. Depending on the embodiment, the touch-sensitive sensor is arranged between the diffuser layer and the luminous foil or behind the luminous foil, i.e. outside the first main radiation direction.

In some further embodiments, an additional cover layer can optionally be provided, which on the one hand protects the diffuser layer from possible damage and on the other hand adjusts the refractive index. The additional cover layer can also be provided with haptic touch elements.

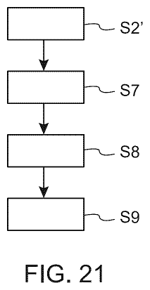

FIG. 21 shows a further embodiment and addition to the method in which, in step S2′, a luminous foil is provided with optoelectronic components which have two main emission directions which are opposite to each other. This makes it possible for the optoelectronic components to emit light on both sides in one operation, which makes it possible to display in different directions. In such a case, the method further comprises step S7, in which a second diffuser layer is applied in such a way that it is arranged downstream of the at least two optoelectronic components with respect to the second main emission direction. Depending on the embodiment, the second diffuser layer is either structured itself, so that it forms a second structured symbol element due to a spatially inhomogeneous distribution of diffuser or absorber particles.

Alternatively, as shown in step S8, a second structured symbol element can also be arranged on the second diffuser layer, wherein the second structured symbol element is not located in front of the second diffuser layer with respect to the second main radiation direction. In an operation of at least one of the at least two optoelectronic components and in plan view of the second diffuser layer along the second main radiation direction, the structured second symbol element visualizes a corresponding symbol to a user.

In step S9, a second touch-sensitive sensor is also arranged, which is configured to detect an exerted touch or pressure along the second main radiation direction and to generate an electrical signal from this. In this way, an optical display and operating element is created which can be operated in the same way from both sides. The symbols generated by the first and second symbol elements can be different for one user. A suitable reflective layer also prevents light from one side from reaching the other side.

Using suitable electrochromic color layers or other measures, the symbols can also be configured differently so that the symbols can be changed depending on the state of the display and operating element. This allows a great deal of flexibility in use, not only for double-sided display and operating elements, but also for single-sided display and operating elements, and creates various display options on transparent surfaces.

### REFERENCE LIST

1 operating element
10 carrier element, carrier foil
11 reflective layer
20 luminous foil
25 optoelectronic component
26, 26′ contact lines
27, 27′ connection, contact pad
28 first main radiation direction
28′ second main radiation direction
30 reflective layer
40 diffuser layer
40′ 51′ diffuser layer with color converter
50, 51 structured symbol element
60 touch-sensitive sensor
70 adhesive layer
71 medium
75, 75a adhesive layer
80 colored layer
90 cover foil layer
95 color filter
100, 101 glass layer
110 haptic touch element
270 insulating layer

1. An operating element, comprising:
a carrier element;
a luminous foil in or on which at least one optoelectronic component for generating light along a first main radiation direction and contact lines connected thereto are arranged;
a diffuser layer arranged after the at least one optoelectronic component with respect to the first main radiation direction;
a structured symbol element which is not arranged in front of the diffuser layer with respect to the first main radiation direction and which is configured to image at least one symbol along the first main radiation direction in a top view onto the diffuser layer and during operation of the at least one optoelectronic component;
a touch-sensitive sensor, which is optionally arranged between the carrier element and the luminous foil and which is configured to detect an exerted touch or an exerted pressure exerted along or in the opposite direction to the first main radiation direction and to generate an electrical signal therefrom; and
at least one reflective layer, which is arranged on the opposite side of the luminous foil with respect to the symbol element and which is configured to reflect light scattered in the opposite direction to the main radiation direction in the main radiation direction.

2. The operating element according to claim 1, wherein a distance between the diffuser layer and at least two optoelectronic components depends on a distance between the at least two optoelectronic components, wherein optionally the at least two optoelectronic components follow a shape of the structured symbol element at least proportionally.

3. The operating element according to claim 1, wherein the reflective layer is arranged between the luminous foil and the touch-sensitive sensor; and/or
wherein the reflective layer comprises a thermally conductive material, in particular Al2O3, a metal or a specular reflective material.

4. The operating element according to claim 1, further comprising:
a second reflective layer, which is arranged between the structured symbol element and the diffuser layer and which in particular comprises a smaller lateral extent than the symbol element;
wherein optionally
the second reflective layer is applied to the side of the symbol element facing the at least one optoelectronic component; and/or
the symbol element is formed with a reflective foil; or
the symbol element is formed with a foil whose side facing the at least one optoelectronic component is reflective.

5. The operating element according to claim 2, further comprising:
an adhesive layer which bonds the luminous foil to the diffuser layer in such a way that its thickness substantially equals the distance between the diffuser layer and the at least two optoelectronic components.

6. The operating element according to claim 1, wherein the structured symbol element is formed by a shadow mask arranged on the diffuser layer; and/or
wherein the structured symbol element is formed by a structuring in the diffusor layer, in particular by a spatial distribution of diffusor particles in the diffusor layer which forms the structuring.

7. The operating element according to claim 1, further comprising at least one of the following layers:
an adhesive layer arranged between the carrier element- and the luminous foil;
a cover foil layer which is arranged after the diffuser layer with respect to the main radiation direction; and
an optionally partially transparent colored layer, which is arranged after the diffuser layer with respect to the main radiation direction, wherein the colored layer is optionally structured and in particular structured similarly to the structured symbol element.

8. The operating element according to claim 1, wherein the diffuser layer comprises converter particles for converting irradiated light of a first wavelength into light of a second wavelength.

9. The operating element according to claim 1, comprising at least two optoelectronic components for generating light of different wavelengths.

10. The operating element according to claim 1, further comprising:
a second main radiation direction, which is oriented substantially opposite to the first main radiation direction;
a second diffuser layer arranged after the at least two optoelectronic components with respect to the second main radiation direction; and;
a structured second symbol element which is not arranged in front of the second diffuser layer with respect to the second main radiation direction and which is configured to image at least one symbol along the main radiation direction in a top view onto the second diffuser layer and during operation of at least one of the at least two optoelectronic components, the reflective layer being arranged between and substantially in the plane of the at least two optoelectronic components.

11. A control panel, in particular for a vehicle, comprising:
a glass element, in particular a pane or a panel; and
the operating element according to claim 1, wherein the operating element is arranged on the glass element in such a way that the glass element forms the carrier element of the operating element, or the carrier element is intimately connected to the glass element.

12. A method for manufacturing an operating element comprising the steps of:
providing a carrier element;
providing a luminous foil in or on which at least two optoelectronic components and contact lines connected thereto are arranged, and the at least two optoelectronic components are configured for generating light along a first main radiation direction in operation;
arranging the luminous foil on the carrier element;
arranging a diffuser layer on the luminous foil, so that in operation, light emitted from the at least two optoelectronic components along the first main radiation direction radiates through the diffuser layer, wherein a distance between the diffuser layer and the at least two optoelectronic components depends on a distance between the at least two optoelectronic components;
arranging a structured symbol element with respect to the first main radiation direction not in front of the diffuser layer, which is configured to image at least one symbol along the first main radiation direction in a top view onto the diffuser layer and during operation of the at least two optoelectronic components;
forming a reflective layer on the side of the luminous foil facing away from the symbol element; and
arranging a touch-sensitive sensor which is configured to detect a touch or pressure exerted along or in the opposite direction to the first main radiation direction and to generate an electrical signal therefrom.

13. The method according to claim 12, wherein arranging the luminous foil on the carrier element comprises bonding the luminous foil to the carrier element by means of an adhesive layer.

14. The method according to claim 12, further comprising:
arranging a cover foil layer which is arranged dafter the diffuser layer with respect to the main radiation direction; and/or
applying an optionally partially transparent colored layer, which is arranged after the diffuser layer with respect to the main radiation direction, wherein the colored layer is optionally structured and in particular structured similarly to the structured symbol element.

15. The method according to claim 12,
wherein the touch-sensitive sensor is arranged between the luminous foil and the diffuser layer; or
wherein the touch-sensitive sensor is arranged after the diffuser layer with respect to the first main radiation direction.

16. The method according to claim 12, wherein
the two optoelectronic components are arranged such that they follow a shape of the structured symbol element.
